(19) United States
(12) Patent Application Publication
(10) Pub. No.: US 2015/0340653 A1
(43) Pub. Date: Nov. 26, 2015

(54) OLED DISPLAY PANEL

(71) Applicant: InnoLux Corporation, Miao-Li County (TW)

(72) Inventors: Yixin YANG, Miao-Li County (TW); Yung-Sheng CHEN, Miao-Li County (TW); Fang Iy WU, Miao-Li County (TW); Cheng-Hsiung LIU, Miao-Li County (TW); Cheng-Hsu CHOU, Miao-Li County (TW)

(21) Appl. No.: 14/695,458

(22) Filed: Apr. 24, 2015

(30) Foreign Application Priority Data
May 23, 2014 (TW) 103118041

(51) Int. Cl. H01L 51/52

(52) U.S. Cl. CPC H01L 51/5256

(57) ABSTRACT

An OLED display panel is disclosed, which comprises: a substrate; an OLED unit disposed on the substrate; and an inorganic-DLC composite layer comprising a first inorganic layer and a first DLC layer, wherein the first inorganic layer and the first DLC layer sequentially laminate on the OLED unit, and the first inorganic layer locates between the OLED unit and the first DLC layer. Herein, a ratio of a thickness of the first inorganic layer to that of the first DLC layer is in a range from 50 to 500.

### CROSS REFERENCE TO RELATED APPLICATION

This application claims the benefits of the Taiwan Patent Application Serial Number 103118041, filed on May 23, 2014, the subject matter of which is incorporated herein by reference.

### BACKGROUND OF THE INVENTION

1. Field of the Invention

The present invention relates to an organic light emitting diode (OLED) display panel and, more particularly, to an OLED display panel with high moisture barrier property and air impermeability.

2. Description of Related Art

OLED display panels are light in weight and ultra-thin in thickness, and also have advantages of high brightness, rapid response, wide viewing angles, no backlight requirement, and flexibility. Hence, OLEDs have great potential to apply on display panels of various electronic devices such as panels of cell phones, mobiles and media players. However, the OLED display panels have disadvantages of poor moisture barrier property and air impermeability.

In the developed OLED display panels, in order to improve the moisture barrier property and air impermeability thereof, an additional barrier layer or protection layer are disposed to enhance moisture and oxygen barrier property thereof to prevent the moisture and oxygen permeation, which may cause the device deteriorated. Generally, most of the materials for the used barrier layers are inorganic materials, and the inorganic material layers are formed through vacuum depositions or sputtering processes. Since the uniformity of the obtained inorganic material layers is usually poor, many pores are generally formed therein, which provides a channel for moisture and oxygen permeation. When the OLED display panel contacts with moisture and oxygen, the moisture and oxygen may permeate into the display device through these pored formed in the inorganic material layers, resulting in the moisture and oxygen impermeability of the inorganic material layers as the barrier layers decreased.

Therefore, it is desirable to provide a novel OLED display panel to obviate the aforementioned problems and improve the moisture barrier property and air impermeability thereof, to improve the operation time thereof.

### SUMMARY OF THE INVENTION

The object of the present invention is to provide an OLED display panel with a diamond-like carbon (DLC) layer to improve moisture barrier property and air impermeability of the OLED display panel, and further increase the operation time thereof.

To achieve the object, the OLED display panel of the present invention comprises: a substrate; an OLED unit disposed on the substrate; and an inorganic-DLC composite layer comprising a first inorganic layer and a first DLC layer, wherein the first inorganic layer and the first DLC layer sequentially laminate on the OLED unit, and the first inorganic layer locates between the OLED unit and the first DLC layer, wherein a ratio of a thickness of the first inorganic layer to that of the first DLC layer is in a range from 50 to 500.

The OLED display panel of the present invention may further comprise one or more inorganic-DLC composite layers sequentially laminating on the OLED unit, wherein each inorganic-DLC composite layer respectively comprises a first inorganic layer and a first DLC layer, and the first inorganic layers and the first DLC layers are alternately arranged.

In addition, the OLED display panel of the present invention may further comprise a second inorganic layer disposed on an outmost layer of the inorganic-DLC composite layers. More specifically, the second inorganic layer is disposed on the outmost first inorganic layer of the inorganic-DLC composite layers.

Furthermore, the OLED display panel of the present invention may further comprise an encapsulating layer disposed between the inorganic-DLC composite layer and the OLED unit. In addition, in the case that the OLED display panel of the present invention comprises plural inorganic-DLC composite layers, an encapsulating layer may further be disposed between two adjacent inorganic-DLC composite layers of the plural inorganic-DLC composite layers.

In the OLED display panel of the present invention having either one or plural inorganic-DLC composite layers, a ratio of a thickness of the inorganic layer to that of the neighboring DLC layer is in a range from 50 to 500, and preferably in a range from 70 to 150.

In addition, in the case that the OLED display panel of the present invention have either one or plural inorganic-DLC composite layers, the thickness of the first or second inorganic layer and the DLC layer is not particularly limited, as long as the thickness ratio thereof satisfy the aforementioned range. Preferably, a thickness of the first or second inorganic layer is in a range from 0.5 μm to 5 μm; and a thickness of the first DLC layer is in a range from 1 nm to 100 nm.

Furthermore, in the case that the OLED display panel of the present invention have either one or plural inorganic-DLC composite layers, there is no particular relationship between the stress of the first or second inorganic layer and the DLC layer. Preferably, a stress of the first or second inorganic layer is larger than that of the first DLC layer to provide an OLED display panel with flexibility.

In the OLED display panel of the present invention, the DLC layer with small and fine particles formed on the inorganic layer can fill pores in the inorganic layer. Hence, the moisture barrier property and air impermeability of the OLED display panel can be improved, and the operation time thereof can further be increased. Meanwhile, the DLC layer with appropriate thickness can exhibit desired light transmittance, so the obtained OLED display panel can be used as a top-emitting OLED display panel.

Other objects, advantages, and novel features of the invention will become more apparent from the following detailed description when taken in conjunction with the accompanying drawings.

### BRIEF DESCRIPTION OF THE DRAWINGS

FIG. 1 is a cross-sectional view of an OLED display panel according to Embodiment 1 of the present invention;

FIG. 2 is a cross-sectional view of an OLED display panel according to Embodiment 2 of the present invention;

FIG. 3 is a cross-sectional view of an OLED display panel according to Embodiment 3 of the present invention;

FIG. 4 is a cross-sectional view of an OLED display panel according to Embodiment 4 of the present invention;

FIG. 5 is a cross-sectional view of an OLED display panel according to Embodiment 5 of the present invention;

FIG. 6 is a cross-sectional view of an OLED display panel according to Embodiment 6 of the present invention; and

FIG. 7 is a cross-sectional view of an OLED display panel according to Comparative Embodiment 1 of the present invention.

### DETAILED DESCRIPTION OF THE PREFERRED EMBODIMENT

The present invention has been described in an illustrative manner, and it is to be understood that the terminology used is intended to be in the nature of description rather than of limitation. Many modifications and variations of the present invention are possible in light of the above teachings. Though each of the various embodiments described below is an OLED display panel, other types of display panel can also be applied to the present invention. In addition, the sizes such as the length and the thickness of the device are not limited to those shown in the figures, and the figures shown in the present specification are used only for explanation of the present invention. Therefore, it is to be understood that within the scope of the appended claims, the invention may be practiced otherwise than as specifically described.

### Embodiment 1

FIG. 1 is a cross-sectional view of an OLED display panel of the present embodiment. As shown in FIG. 1, the OLED display panel of the present embodiment comprises: a substrate 11; an OLED unit 12 disposed on the substrate 11; and an inorganic-DLC composite layer 2 comprising a first inorganic layer 21 and a first DLC layer 22, wherein the first inorganic layer 21 and the first DLC layer 22 sequentially laminate on the OLED unit 12, and the first inorganic layer 21 locates between the OLED unit 12 and the first DLC layer 22.

In the present embodiment, the substrate 11 can be any rigid substrate such as a glass substrate or any flexible substrate such as a plastic substrate generally used in the art. In addition, the structure of the OLED unit 12 can be the known structure comprising two electrodes and an organic light emitting layer disposed between the two electrodes, and at least one of an electron injection layer, an electron transporting layer, a hole transporting layer and a hole injection layer may be selectively comprised therein. The materials for the aforementioned electrodes and layers can be known materials for the electrodes or organic materials generally used in the art, and the descriptions thereof are not illustrated herein. Furthermore, the material for the first inorganic layer 21 can be any inorganic material capable of providing moisture barrier property and air impermeability generally used in the art, such as metal oxides, metal fluorides, metal nitrides, metal carbides, metal carbonitrides, metal oxynitrides, metal borides, metal boric oxides, metal silicides, silicon oxynitrides, silicon nitrides and silicon oxides. Preferably, the material for the first inorganic layer 21 is SiO₂, Si₄N₃, TiO₂, Al₂O₃, ZrO₂ or AlN.

Although the aforementioned inorganic materials can provide a certain moisture barrier property and air impermeability, there are still some pores or cracks existing in the formed inorganic layer due to large particle sizes of the inorganic materials. Hence, in OLED display panel of the present embodiment, the fine and compact DLC layer having small particle sizes is formed on the inorganic layer to fill the pores or cracks in the inorganic layer. Meanwhile, the film formed by DLC is fine and compact, so the moisture barrier property thereof can further be improved to prevent moisture permeating therethrough. Hence, the moisture barrier property and air impermeability of the OLED display panel can further be improved.

DLC is a kind of amorphous carbon which can be obtained by any known method used in the art, such as physical vapor depositions (for example, arc discharge methods, laser ablation depositions or sputtering processes), and radio-frequency or pulsed chemical vapor deposition. However, the formation of the DLC layer of the present invention is not limited thereto.

In the present embodiment, there is a specific ratio of the thicknesses of the first inorganic layer 21 to that of the first DLC layer 22 to achieve the purpose of filling the pores or cracks in the first inorganic layer 21 with the first DLC layer 22. In addition, as the thickness of the first inorganic layer 21 increased, the sizes of the pores or cracks formed therein are also increased. Hence, the thickness of the first DLC layer 22 has to be increased to achieve the purpose of filling the pores or cracks in the first inorganic layer 21 with the first DLC layer 22. Herein, a ratio of a thickness of the first inorganic layer 21 to that of the first DLC layer 22 is in a range from 50 to 500, and preferably in a range from 70 to 150.

In addition, the first inorganic layer 21 has to have a certain thickness to achieve certain moisture barrier property and air impermeability. Hence, in the present embodiment, the thickness of the first inorganic layer 21 is in a range from 0.5 μm to 5 μm, and preferably in a range from 1 μm to 3 μm.

Furthermore, in the case that the OLED display panel of the present embodiment is used as a top-emitting OLED display panel, the transmittance thereof may be related to the thickness of the first DLC layer 22 comprised therein. Hence, in the present embodiment, the thickness of the first DLC layer 22 is in a range from 1 nm to 100 nm, and preferably in a range from 10 nm to 30 nm.

In addition, in the OLED display panel of the present embodiment, the stresses of the first inorganic layer 21 and the first DLC layer 22 are decided by the preparation processes and the thicknesses thereof, and not particularly limited. Herein, the stress of the first DLC layer 22 may be adjusted through the preparation process of the first DLC layer 22.

If it is desired to provide an OLED display panel with decreased stress to improve the flexibility thereof, a stress of the first inorganic layer 21 is preferably larger than that of the first DLC layer 22. However, in other embodiments of the present invention, the stress of the first inorganic layer 21 may be smaller than that of the first DLC layer 22. In both cases that the stress of the first inorganic layer 21 is either larger or smaller than that of the first DLC layer 22, it is preferably to laminate the first inorganic layer 21 and the first DLC layer 22 in a form that a flexible layer and a rigid layer are alternately laminated to decrease the overall stress of the obtained OLED display panel and improve the flexibility thereof.

### Embodiment 2

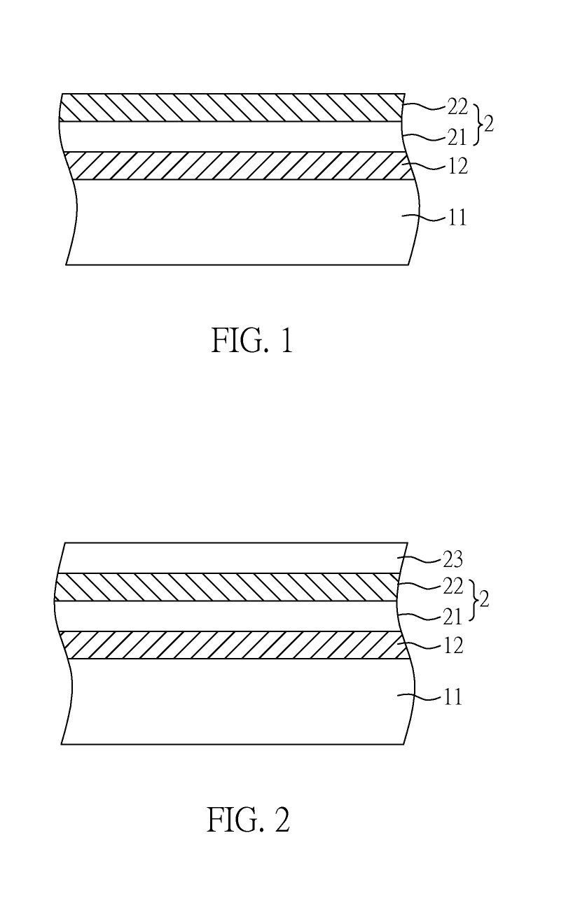

FIG. 2 is a cross-sectional view of an OLED display panel of the present embodiment. As shown in FIG. 2, the structure of the OLED display panel of the present embodiment is similar to that illustrated in Embodiment 1, except that a second inorganic layer 23 is further comprised in the OLED display panel of the present embodiment, which is disposed on the inorganic-DLC composite layer 2.

In the present embodiment, the ratio of the thickness of the second inorganic layer 23 to that of the adjacent first DLC layer 22 is similar to the ratio of the thickness of the first inorganic layer 21 to that of the adjacent first DLC layer 22 illustrated in Embodiment 1, and the thickness and material of the second inorganic layer 23 are also similar to those of the first inorganic layer 21 illustrated in Embodiment 1. Hence, the descriptions thereof are not illustrated herein.

Herein, the porosity of the second inorganic layer 23 laminated on the first DLC layer 22 can be decreased due to the fine and compact structure and highly smooth surface of the first DLC layer 22.

### Embodiment 3

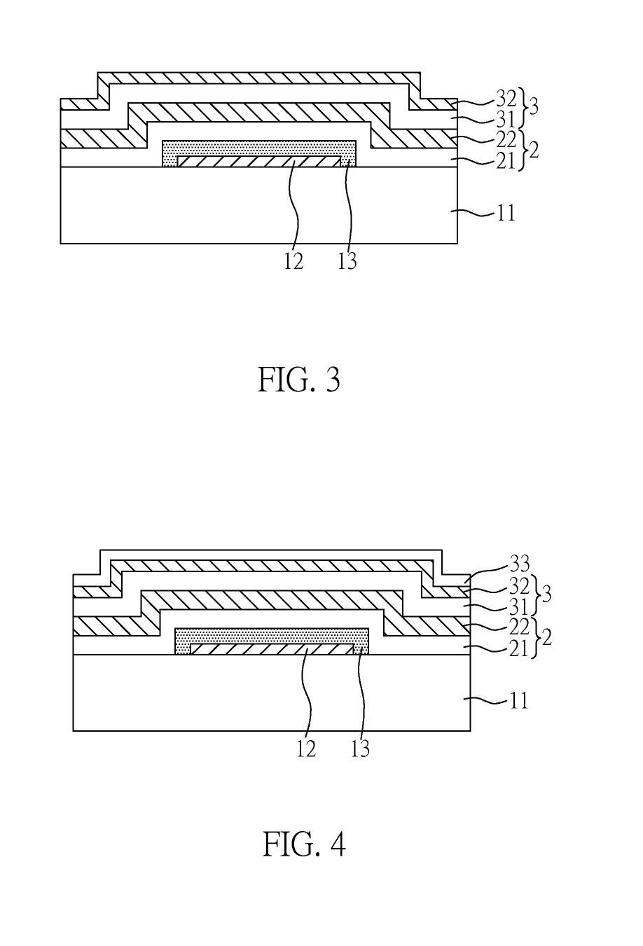

FIG. 3 is a cross-sectional view of an OLED display panel of the present embodiment. As shown in FIG. 3, the structure of the OLED display panel of the present embodiment is similar to that illustrated in Embodiment 1, except that the OLED display panel of the present embodiment further comprises plural inorganic-DLC composite layers 2, 3 and an encapsulating layer 13.

In the present embodiment, the encapsulating layer 13 is disposed between the inorganic-DLC composite layer 2 and the OLED unit 12, which can be made of any organic encapsulating material generally used in the art, such as silane-, acylate- and epoxy-based polymers; but the present invention is not limited thereto.

In addition, in the present embodiment, as shown in FIG. 3, the OLED display panel of the present embodiment comprises plural inorganic-DLC composite layers 2, 3 sequentially laminating on the OLED unit 12. Herein, each inorganic-DLC composite layer 2, 3 respectively comprises the first inorganic layer 21, 31 and the first DLC layer 22, 32, and the first inorganic layers 21, 31 and the first DLC layers 22, 32 are alternately arranged.

Herein, a ratio of a thickness of the first inorganic layers 21, 31 to that of the neighboring first DLC layers 22, 32 is respectively in a range from 50 to 500, and preferably in a range from 70 to 150. In addition, the thicknesses and the materials of the first inorganic layers 21, 31 and the first DLC layers 22, 32 are similar to those described in Embodiment 1, and the descriptions thereof are not present herein. Furthermore, in the case that the OLED display panel of the present embodiment is used as a top-emitting OLED display panel, an total thickness of the first DLC layers 22, 32 is equal to or smaller than 100 nm.

### Embodiment 4

FIG. 4 is a cross-sectional view of an OLED display panel of the present embodiment. As shown in FIG. 4, the structure of the OLED display panel of the present embodiment is similar to that illustrated in Embodiment 3, except that a second inorganic layer 33 is further comprised in the OLED display panel of the present embodiment, which is disposed on the inorganic-DLC composite layer 3. In the present embodiment, the thickness and the material for the second inorganic layer 33 are similar to those disclosed in Embodiment 2, and the descriptions thereof are not illustrated herein.

### Embodiment 5

FIG. 5 is a cross-sectional view of an OLED display panel of the present embodiment. As shown in FIG. 5, the structure of the OLED display panel of the present embodiment is similar to that illustrated in Embodiment 3, except that an encapsulating layer 13 is disposed between two adjacent inorganic-DLC composite layers 2, 3. Herein, a ratio of a thickness of each first inorganic layers 21, 31 to that of the neighboring first DLC layers 22, 32 is respectively in a range from 50 to 500, and preferably in a range from 70 to 150.

### Embodiment 6

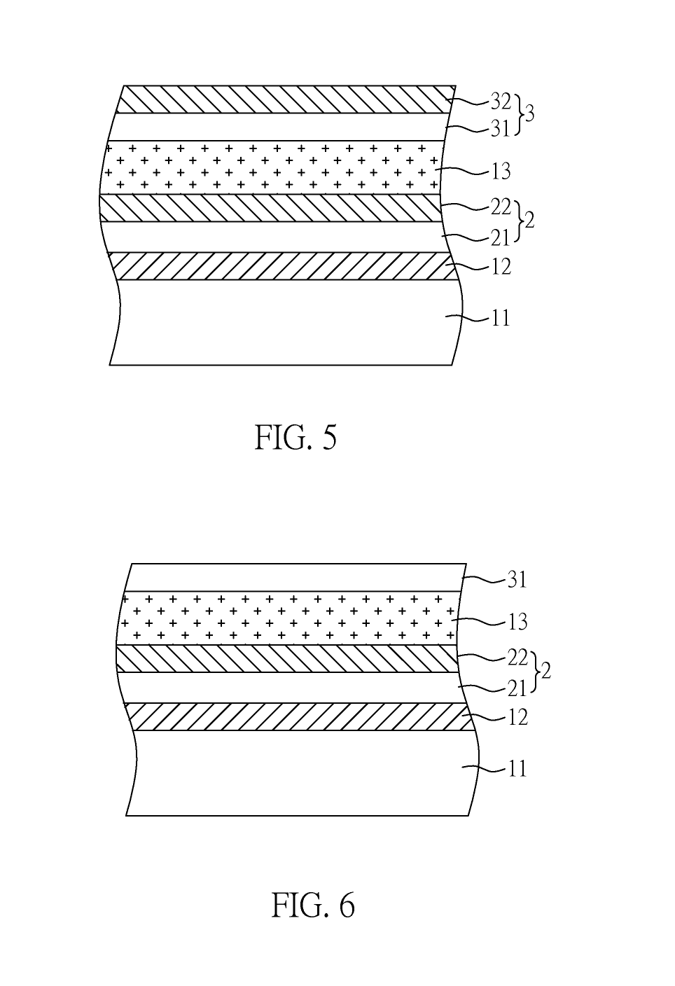

FIG. 6 is a cross-sectional view of an OLED display panel of the present embodiment. As shown in FIG. 6, the structure of the OLED display panel of the present embodiment is similar to that illustrated in Embodiment 5, except that the first inorganic layer 31 is disposed on the encapsulating layer 13 and no first DLC layer is disposed on the encapsulating layer 13.

Furthermore, the display panel provided by the aforementioned embodiments of the present invention can be applied to any electronic device equipped with an OLED display panel, such as mobile phones, notebooks, cameras, video cameras, music players, navigation systems, and televisions.

### Comparative Embodiment 1

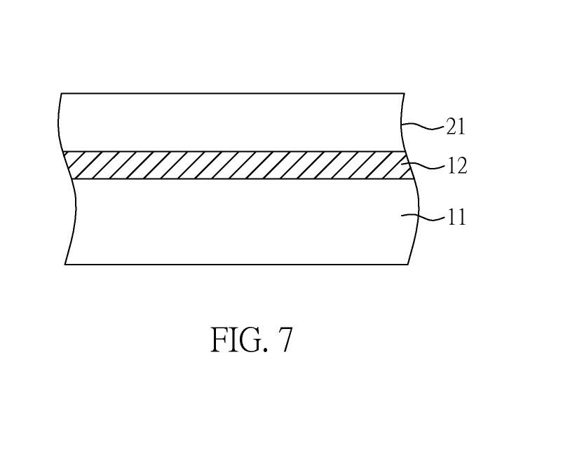

FIG. 7 is a cross-sectional view of an OLED display panel of the present comparative embodiment. As shown in FIG. 7, the structure of the OLED display panel of the present comparative embodiment is similar to that illustrated in Embodiment 1, except that only the first inorganic layer 21 is disposed on the OLED unit 12 and no first DLC layer is disposed on the OLED unit 12.

### Comparative Embodiment 2

The structure of the OLED display panel of the present comparative embodiment is similar to that illustrated in Embodiment 1, except that the first DLC layer of the Embodiment 1 is replaced with an encapsulating layer.

### Testing Example

Herein, Reliability analysis (RA) is performed on the OLED display panels of Embodiment 2, and Comparative embodiments 1-2. As shown in FIG. 2, the materials of the first inorganic layer 21 and the second inorganic layer 23 in the OLED display panel of Embodiment 2 are silicon nitride, and the thicknesses thereof are respectively 1.975 μm and 2 μm, while the thickness of the first DLC layer 22 is 25 nm. As shown in FIG. 7, the material of the first inorganic layer 21 in the OLED display panel of Comparative embodiment 1 is silicon nitride, and the thickness thereof is 4 μm. As shown in FIG. 1, the material of the first inorganic layer 21 in the OLED display panel of Comparative embodiment 2 is silicon nitride, and the thickness thereof is 4 μm; while the material of the encapsulating layer thereof is epoxy resin film and the thickness thereof is about 3 μm.

After Reliability analysis in an environment of 85° C. and 85% humidity, the operation time of the OLED display panel of Comparative embodiment 2 is about 120 hours and that of Comparative embodiment 1 is less than 120 hours. On the contrary, the operation time of the OLED display panel of Embodiment 2 is at least about 240 hours. These results indicate that the operation time of the OLED display panel can be greatly increased due to the disposition of the DLC layer of the present invention, which can improve the moisture barrier property and air impermeability of the OLED display panel.

Although the present invention has been explained in relation to its preferred embodiment, it is to be understood that many other possible modifications and variations can be made without departing from the spirit and scope of the invention as hereinafter claimed.

What is claimed is:

1. An a OLED display panel, comprising:
a substrate;
an OLED unit disposed on the substrate; and
an inorganic-DLC composite layer comprising a first inorganic layer and a first DLC layer, wherein the first inorganic layer and the first DLC layer sequentially laminate on the OLED unit, and the first inorganic layer locates between the OLED unit and the first DLC layer,
wherein a ratio of a thickness of the first inorganic layer to that of the first DLC layer is in a range from 50 to 500.

2. The OLED display panel as claimed in claim 1, wherein the ratio of the thickness of the first inorganic layer to that of the first DLC layer is in a range from 70 to 150.

3. The OLED display panel as claimed in claim 1, wherein a thickness of the first inorganic layer is in a range from 0.5 μm to 5 μm.

4. The OLED display panel as claimed in claim 1, wherein a thickness of the first DLC layer is in a range from 1 nm to 100 nm.

5. The OLED display panel as claimed in claim 1, further comprising a second inorganic layer disposed on the inorganic-DLC composite layer.

6. The OLED display panel as claimed in claim 1, further comprising an encapsulating layer disposed between the inorganic-DLC composite layer and the OLED unit.

7. The OLED display panel as claimed in claim 1, wherein a stress of the first inorganic layer is larger than that of the first DLC layer.

8. The OLED display panel as claimed in claim 1, wherein the inorganic-DLC composite layer comprising plural inorganic-DLC composite layers sequentially laminating on the OLED unit, wherein each inorganic-DLC composite layer respectively comprises the first inorganic layer and the first DLC layer, and wherein the first inorganic layers and the first DLC layers are alternately arranged.

9. The OLED display panel as claimed in claim 8, further comprising a second inorganic layer disposed on an outmost layer of the inorganic-DLC composite layers.

10. The OLED display panel as claimed in claim 8, further comprising an encapsulating layer disposed between two adjacent inorganic-DLC composite layers of the plural inorganic-DLC composite layers.
